(19) United States
(12) Patent Application Publication
(10) Pub. No.: US 2011/0284258 A1
(43) Pub. Date: Nov. 24, 2011

(54) CASING OF ELECTRONIC DEVICE

(75) Inventors: Ching-Huei Chang, Zhonghe City (TW); Ko-Hsien Lee, Dayuan Township (TW); Ching-Feng Hsieh, Taipei City 108 (TW)

(73) Assignee: ASKEY COMPUTER CORP., TAIPEI (TW)

(21) Appl. No.: 12/818,609

(22) Filed: Jun. 18, 2010

(30) Foreign Application Priority Data
May 21, 2010 (TW) 099209629

(51) Int. Cl. H05K 5/00

(52) U.S. Cl. 174/50

(57) ABSTRACT

A casing of an electronic device includes an opening securely covered and remained unused to prevent the opening from being exposed. The casing includes a casing body and a cover plate, and the casing body has an opening and a thermoplastic pillar installed vertically inside the casing body. The thermoplastic pillar is proximate to the opening and includes a fixed portion formed at an end of the thermoplastic pillar. The cover plate is covered onto the casing body to cover the opening and has a positioning hole for passing the thermoplastic pillar, and the positioning hole is smaller than the fixed portion, such that the opening of the casing can be sealed and remained unused for a long time to achieve the effects of preventing internal electronic components from being exposed, maintaining the aesthetic appearance, preventing external pollutants from entering, and extending the lifespan of the electronic device.

### CROSS-REFERENCE TO RELATED APPLICATION

This non-provisional application claims priority under 35 U.S.C. §119(a) on Patent Application No(s). 099209629 filed in Taiwan, R.O.C. on May 21, 2010, the entire contents of which are hereby incorporated by reference.

### FIELD OF THE TECHNOLOGY

The present invention relates to a casing of an electronic device, in particular to a casing having an opening securely sealed and remained unused for a long time to achieve the effects of preventing internal electronic devices from being exposed to the outside, maintaining the aesthetic appearance of the electronic device, preventing external pollutants from entering into the electronic device, and extending the lifespan of the electronic device.

### BACKGROUND

As science and technology advance, information flows become increasingly quicker, and many electronic devices are introduced to the market accordingly, and the first part of an electronic device seen and touched by people is a casing of the electronic device, and the casing having many openings is made as required in the manufacturing process of the electronic device. For example, a hole is formed on a mold and reserved for a demolding purpose. After the electronic device is assembled, the openings are provided for viewing the internal electronic devices and thus making the appearance of the electronic device unpresentable. In addition, external pollutants may enter into the electronic device through the openings and shorten the lifespan of the electronic device. To overcome the aforementioned shortcomings, some manufacturers seal the openings of the electronic device after the electronic device is assembled, and such openings will be not used anymore. With reference to FIGS. 1 to 3 respectively for an exploded view and a perspective view of a conventional electronic device and a schematic view of a conventional casing of an electronic device after the openings are sealed, the conventional electronic device comprises a casing and a circuit board 7, wherein the casing includes a casing body 9 and a cover plate 8, and the casing body 9 includes an upper casing body 92 and a lower casing body 91, and the lower casing body 91 has various protruded platforms 911, 911a, 911b, and various openings 9111, 9111a, 9111b formed on distal surfaces of various protruded platforms 911, 911a, 911b respectively. In the conventional casing, various cover plates 8, 8a, 8b are manually attached onto various protruded platforms 911, 911a, 911b for sealing various openings 9111, 9111a, 9111b. However, the manual attachment is not secure, and the cover plates 8, 8a, 8b are not attached securely onto the protruded platforms 911, 911a, 911b, such that after the electronic device has been used for a long time, the cover plates 8, 8a, 8b may be warped or may even fall off. Furthermore, the electronic device generates a high temperature during use, and the environment of using electronic device may have moisture, and the high temperature and moisture will deteriorate the cohesive force of the glue for attaching the cover plates 8, 8a, 8b, and finally the cover plates 8, 8a, 8b are warped or fall off. The cover plates 8, 8a, 8b are installed for the purpose of sealing the openings and no longer using the opening anymore, and the cover plates 8, 8a, 8b will not be removed again. However, once if the cover plates 8, 8a, 8b are warped or fall off, the cover plates 8, 8a, 8b will be unable to seal the openings 9111, 9111a, 9111b securely, and the electronic device will have the aforementioned issues again. Viewing the internal electronic devices through the unused opening makes the appearance of the electronic device ugly; and external pollutants may enter into the electronic device through the unused opening and shorten the lifespan of the electronic device.

Therefore, it is a main subject for the invention to provide a casing of an electronic device having an opening securely sealed and remained unused for a long time to achieve the effects of preventing internal electronic devices from being exposed to the outside, maintaining the aesthetic appearance of the electronic device, preventing external pollutants from entering into the electronic device, and extending the lifespan of the electronic device.

### SUMMARY

In view of the shortcomings of the conventional casing, it is a primary objective of the present invention to provide a casing of an electronic device having an opening securely sealed and remained unused for a long time to achieve the effects of preventing internal electronic devices from being exposed to the outside, maintaining the aesthetic appearance of the electronic device, preventing external pollutants from entering into the electronic device, and extending the lifespan of the electronic device.

To achieve the foregoing objective, the present invention discloses a casing of an electronic device comprising: a casing body, including an opening and a plurality of thermoplastic pillars installed vertically inside the casing body, wherein each thermoplastic pillar is disposed proximate to the opening and includes a fixed portion formed at an end of the thermoplastic pillar; and a cover plate, covered onto the interior of the casing body and provided for covering the opening, and having a plurality of positioning holes for passing the thermoplastic pillars respectively, wherein the positioning hole is smaller than the fixed portion.

In the casing in accordance with the present invention, the opening is securely sealed and remained unused for a long time to achieve the effects of preventing the internal electronic devices from being exposed to the outside, maintaining the aesthetic appearance of the electronic device, preventing external pollutants to enter into the electronic device, and extending the lifespan of the electronic device.

### BRIEF DESCRIPTION OF THE DRAWINGS

FIG. 1 is an exploded view of a conventional electronic device;

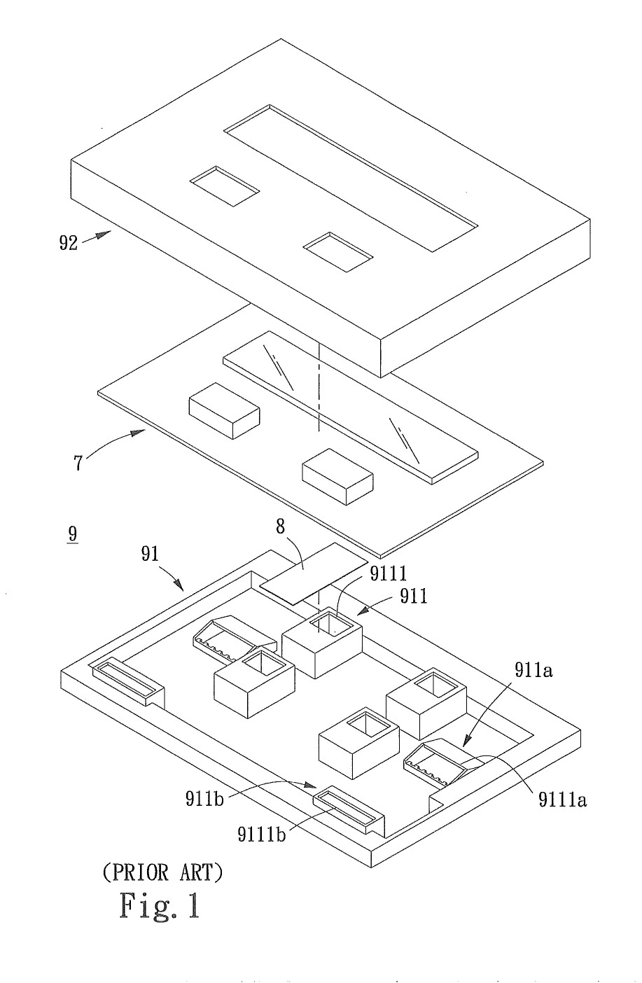

FIG. 2 is a perspective view of a conventional electronic device;

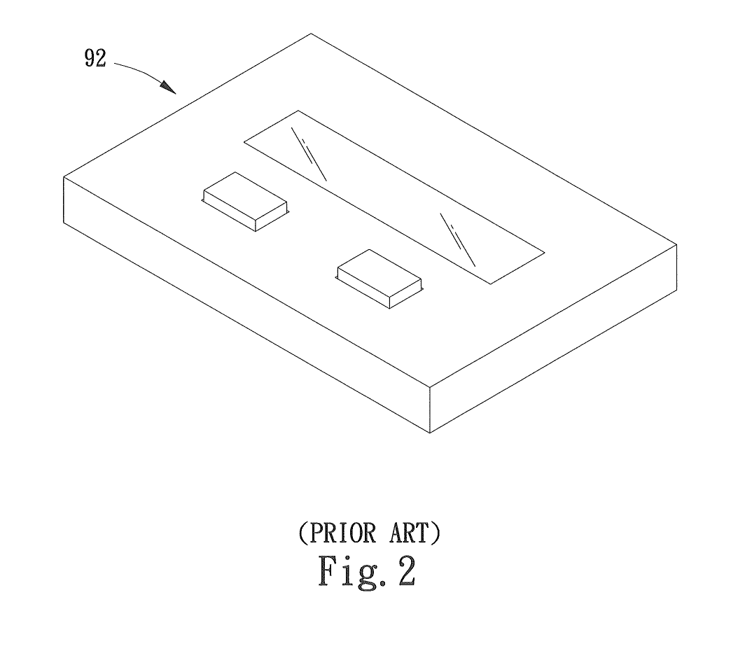

FIG. 3 is a schematic view of a conventional casing of an electronic device after an opening is sealed;

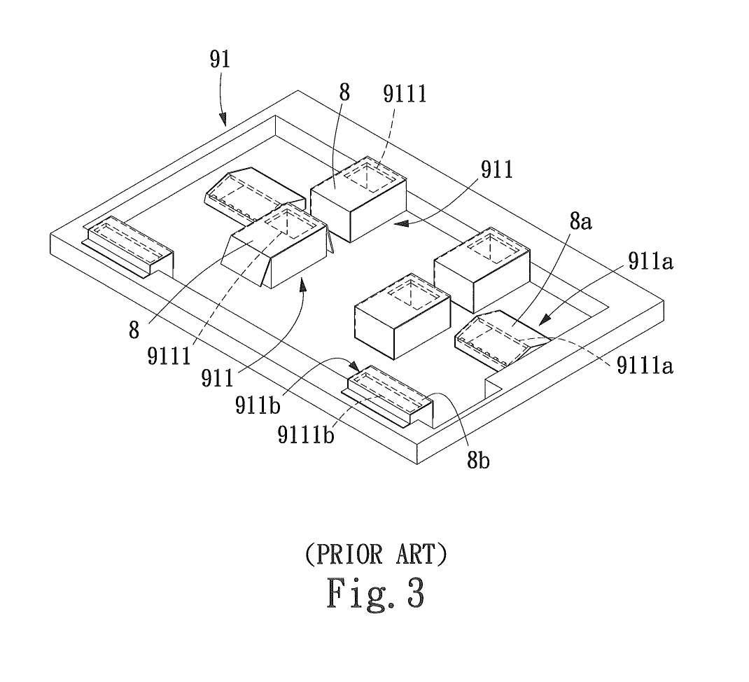

FIG. 4 is an exploded view of a preferred embodiment of the present invention;

FIG. 5 is another exploded view of a preferred embodiment of the present invention;

FIG. 6 is a schematic view of a preferred embodiment of the present invention after an opening is sealed;

FIG. 7 is a cross-sectional side view of section A-A of FIG. 6;

FIG. 8 is an exploded view of an application in accordance with a preferred embodiment of the present invention; and

FIG. 9 is a perspective view of an application in accordance with a preferred embodiment of the present invention.

### DETAILED DESCRIPTION

The objects, characteristics and effects of the present invention will become apparent with the detailed description of the preferred embodiments and the illustration of related drawings as follows.

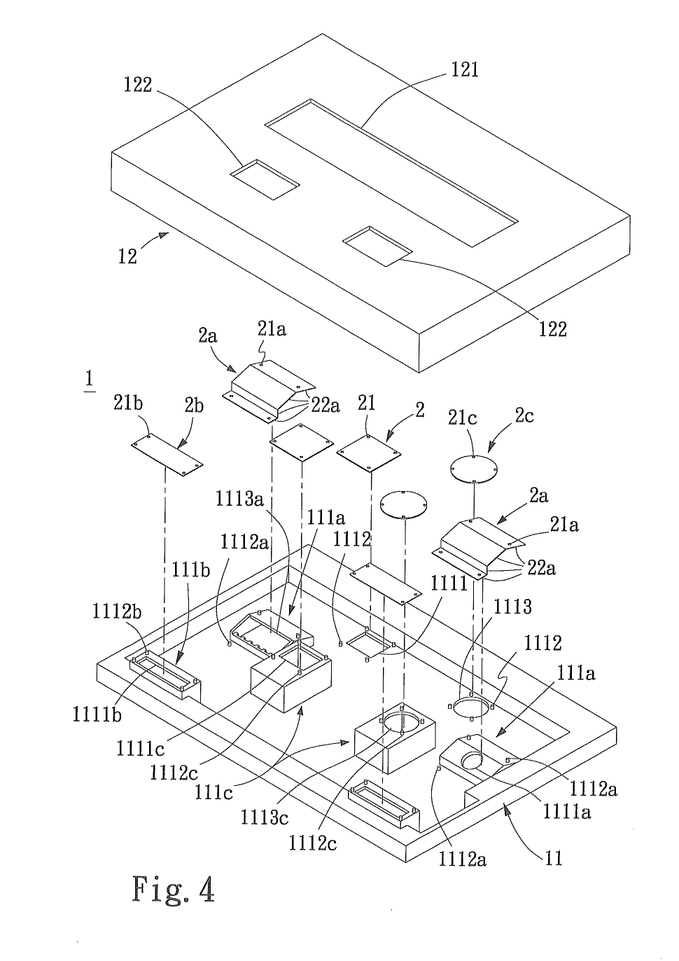

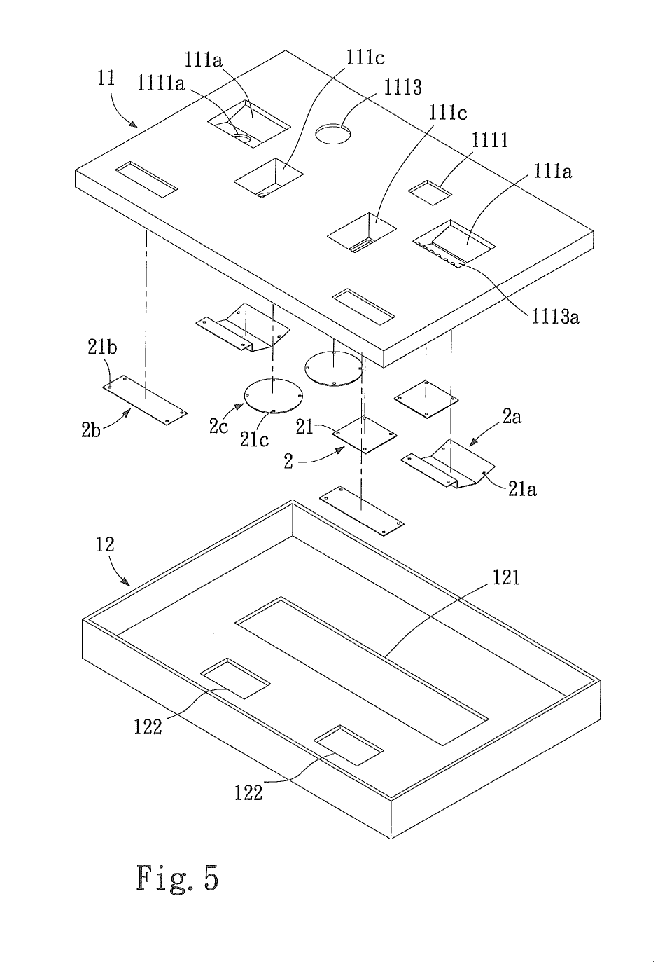

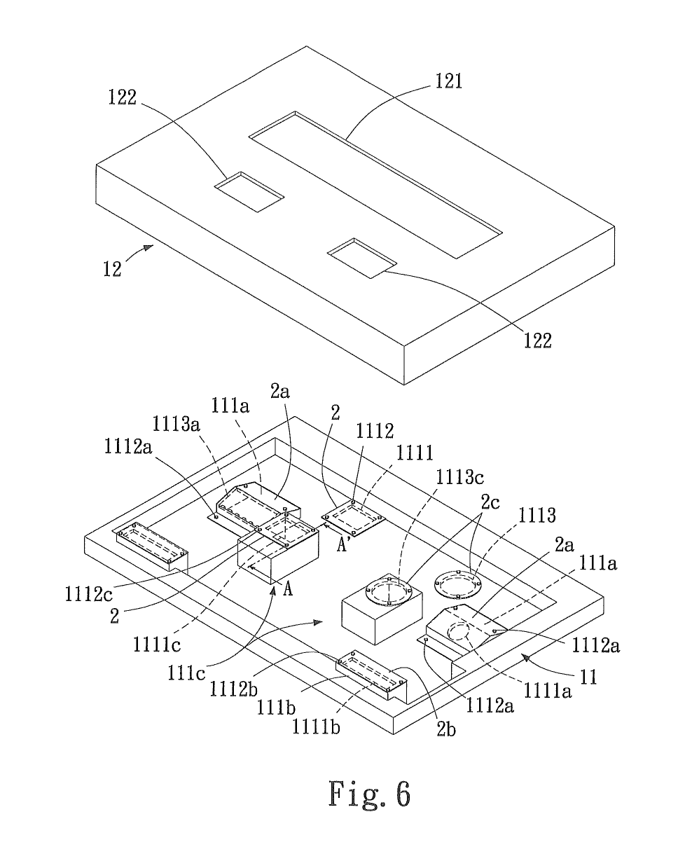

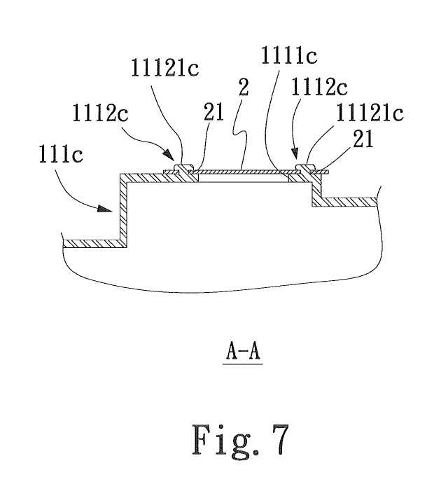

With reference to FIGS. 4 to 7 respectively for exploded views of a preferred embodiment of the present invention and a cross-sectional side view of section A-A of FIG. 6, a casing of an electronic device of the present invention comprises a casing body 1 and a plurality of cover plates 2, 2a, 2b, 2c, wherein the casing body 1 includes an upper casing body 12 and a lower casing body 11 to cope with different assembling configurations, and the casing body 1 includes a plurality of openings 1111, 1111a, 1111b, 1111c, 1113, 1113a, 1113c which are not used anymore after the electronic device is assembled, and the openings 1111, 1111a, 1111b, 1111c, 1113, 1113a, 1113c are generally produced during the manufacturing process of the electronic device, and the quantity of openings 1111, 1111a, 1111b, 1111c, 1113, 1113a, 1113c can be one or more, and the casing body 1 includes a plurality of thermoplastic pillars 1112, 1112a, 1112b, 1112c installed vertically towards the interior of the casing body 1, and the thermoplastic pillars 1112, 1112a, 1112b, 1112c are integrally formed with the casing body 1, and the thermoplastic pillars 1112, 1112a, 1112b, 1112c are installed at positions proximate to the openings 1111, 1111a, 1111b, 1111c, 1113, 1113a, 1113c to minimize the using area of the cover plate 2, 2a, 2b, 2c. In FIG. 7, a fixed portion 11121c is formed at an end of the thermoplastic pillar 1112c, and the cover plates 2, 2a, 2b, 2c can be mylars used for covering the openings 1111, 1111a, 1111b, 1111c, 1113, 1113a, 1113c, and the cover plates 2, 2a, 2b, 2c include a plurality of positioning holes 21, 21a, 21b, 21c for passing the thermoplastic pillars 1112, 1112a, 1112b, 1112c respectively. In FIG. 7, the area of the positioning holes 21 is smaller than the area of the fixed portions 11121c such that the cover plate 2 is restricted and fixed by the fixed portions 11121c, wherein the fixed portions 11121c are formed at an end of the thermoplastic pillars 1112c by a hot pressing process, and the area of the fixed portions 11121c is greater than the area of the positioning holes 21.

The casing body 1 further includes a plurality of protruded platforms 111a, 111b, 111c, and the quantity of protruded platforms 111a, 111b, 111c can be one or more, and the openings 1111a, 1111b, 1111c, 1113a, 1113c are disposed on distal surfaces of the protruded platforms 111a, 111b, 111c respectively, and the protruded platforms 111a, 111b, 111c can be hollow and produced for the purpose of assembling, expanding or manufacturing the electronic device.

The thermoplastic pillars 1112a, 1112b, 1112c are installed vertically on the protruded platforms 111a, 111b, 111c to minimize the using area of the cover plates 2a, 2b, 2c.

The openings 1111, 1111b, 1111c are in a polygonal shape to cope with different requirements, and the thermoplastic pillars 1112, 1112b, 1112c are installed proximate to end points of the openings 1111, 1111b, 1111c for minimizing the using area of the cover plates 2, 2b, and the cover plates 2, 2b are in a shape corresponding to the shape of the openings 1111, 1111b, 1111c in hope of covering the openings 1111, 1111b, 1111c by a minimal area, and the positioning holes 21, 21b are formed proximate to end points of the cover plates 2, 2b for preventing the end points of the cover plates 2, 2b from being warped.

The openings 1113, 1113c are in a circular shape to cope with different requirements, and the thermoplastic pillars 1112, 1112c are distributed uniformly in the neighborhood around the circumference of the openings 1113, 1113c to minimize the using area of the cover plate 2c, and the cover plate 2c is in a shape corresponding to the shape of the openings 1113, 1113c in hope of covering the openings 1113, 1113c by a minimal using area, and the positioning holes 21c are distributed uniformly in the neighborhood around the circumference of the cover plate 2c to prevent the cover plate 2c from being warped from the circumference of the cover plate 2c.

In addition, a portion of the thermoplastic pillar 1112a can be installed vertically from the protruded platform 111a, and another portion of the thermoplastic pillar 1112a is installed vertically from the casing body 1 to cope with the protruded platforms 111 in different shapes and the openings 1111a, 1113a at different positions.

Similarly, the openings 1113a are in a polygonal shape to cope with different requirements, and the thermoplastic pillars 1112a are installed proximate to an end point of the opening 1113a to minimize the using area of the cover plate 2a, The cover plate 2a includes a plurality of plates 22a rotably coupled to one another, such that after the cover plates 2a is bent, the cover plate 2a corresponds to the protruded platform 111a in various different shapes, and the positioning hole 21a is formed at the outermost plate 22a for preventing the cover plate 2a from being warped from both sides of the plate 22a.

Similarly, the opening 1111a is in a circular shape to cope with different requirements, and the thermoplastic pillars 1112a are distributed uniformly in the neighborhood around the circumference of the opening 1111a to minimize the using area of the cover plate 2a, and the cover plate 2a includes a plurality of plates 22a rotably coupled to one another, such that after the cover plate 2a is bent, the cover plate 2a corresponds to the protruded platform 111a in various different shapes, and the positioning hole 21a is formed at the outermost plate 22a for preventing the cover plate 2a from being warped from both sides of the plate 22a.

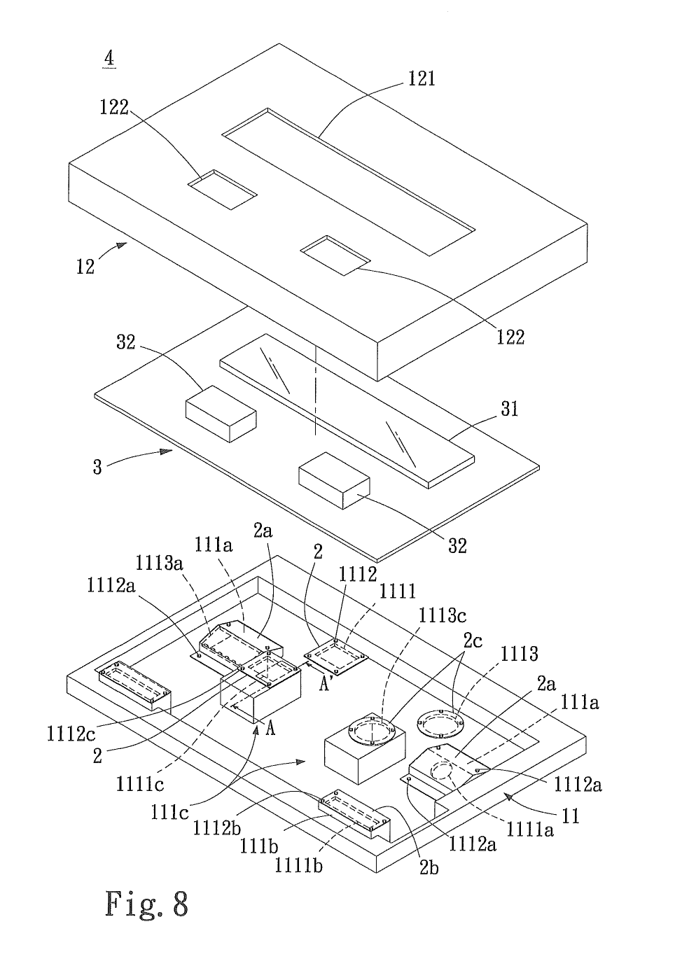

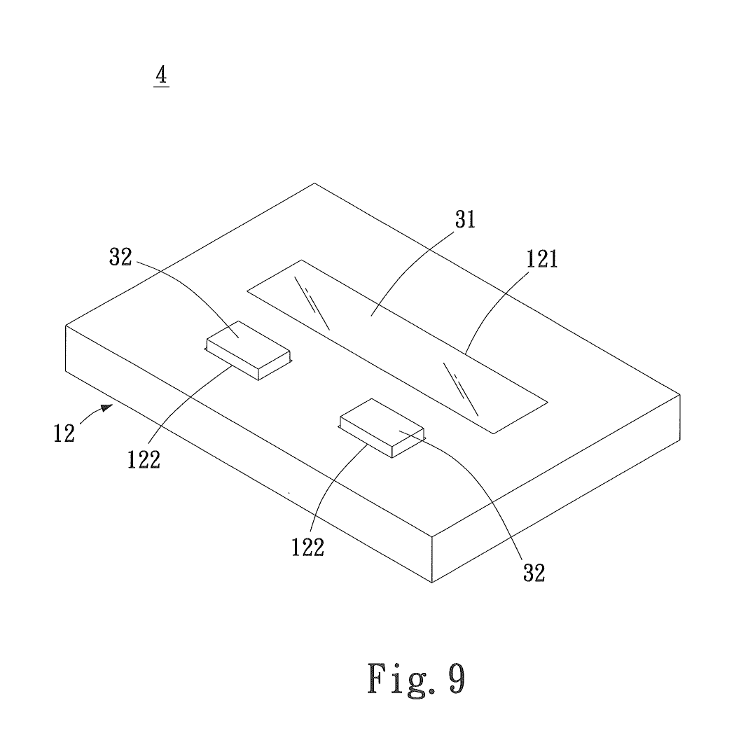

With reference to FIGS. 8 and 9 respectively for an exploded view and a perspective view of a casing of an electronic device in accordance with a preferred embodiment of the present invention, the casing having an installed circuit board 3 is assembled into an electronic device 4. In this preferred embodiment, a casing body 1 includes an upper casing body 12 and a lower casing body 11, and the upper casing body 12 includes a plurality of penetrating holes 121, 122, and the lower casing body 11 includes the aforementioned openings 1111, 1111a, 1111b, 1111c, 1113, 1113a, 1113c, thermoplastic pillars 1112, 1112a, 1112b, 1112c, and protruded platforms 111a, 111b, 111c, wherein the covers plate 2, 2a, 2b, 2c are installed to form the casing of an electronic device in accordance with the present invention, and a display screen 31 and a press button 32 are installed onto the circuit board 3. During the assembling process, the lower casing body 11 is assembled according to the aforementioned structure of the invention, and then the display screen 31 and the press button 32 of the circuit board 3 are arranged at the penetrating holes 121, 122 of the upper casing body 12 respectively, and finally the upper casing body 12 and the lower casing body 11 are engaged with each other to form the electronic device 4. Therefore, the casing of an electronic device in accordance with the present invention includes the openings securely sealed and remained unused for a long time to achieve the effects of preventing the internal electronic devices from being exposed to the outside, maintaining the aesthetic appearance of the electronic device, preventing external pollutants from entering into the electronic device, and extending the lifespan of the electronic device.

While the invention has been described by means of specific embodiments, numerous modifications and variations could be made thereto by those skilled in the art without departing from the scope and spirit of the invention set forth in the claims.

What is claimed is:

1. A casing of an electronic device, comprising:
a casing body, including an opening and a plurality of thermoplastic pillars installed in the casing body, and each thermoplastic pillar being disposed proximate to the opening and having a fixed portion formed at an end of the thermoplastic pillar; and
a cover plate, covered onto the interior of the casing body for covering the opening, and having a plurality of positioning holes for passing the thermoplastic pillars respectively, and the positioning hole being smaller than the fixed portion.

2. The casing of an electronic device as recited in claim 1, wherein the casing body further includes a protruded platform, and the opening is formed at the protruded platform.

3. The casing of an electronic device as recited in claim 2, wherein the thermoplastic pillars are installed vertically on the protruded platform.

4. The casing of an electronic device as recited in claim 1, wherein the opening is in a polygonal shape, and each thermoplastic pillar is installed proximate to an end point of the opening.

5. The casing of an electronic device as recited in claim 4, wherein the cover plate has a shape corresponding to the shape of the opening, and each positioning hole is formed proximate to an end point of the cover plate.

6. The casing of an electronic device as recited in claim 1, wherein the cover plate includes a plurality of plates connected with one another, and each positioning hole is formed at the outermost plate.

7. The casing of an electronic device as recited in claim 1, wherein the opening is in a circular shape, and each thermoplastic pillar is distributed uniformly in the neighborhood around the circumference of the opening.
